(19) United States
(12) Patent Application Publication
(10) Pub. No.: US 2003/0227020 A1
(43) Pub. Date: Dec. 11, 2003

(54) Light emitting apparatus with current regulation function

(75) Inventors: Kuo-Hsin Huang, Hsinchu (TW); Yen-Cheng Chen, Hsinchu (TW); Chun-Hsien Liu, Hsinchu (TW)

Correspondence Address: BAKER BOTTS L.L.P., 2001 Ross Avenue, Dallas, TX, 75201-2980, US

(73) Assignee: Excellence Optoelectronics Inc.

(21) Appl. No.: 10/166,997

(22) Filed: Jun. 10, 2002

(51) Int. Cl. H01L 27/15

(52) U.S. Cl. 257/79

(57) ABSTRACT

A light emitting apparatus with current regulated function includes a light emitting diode (LED), and an integrated circuit chip (IC chip). The IC chip regulates current through the LED. Therefore current is constant and does not change with different kind of LED or different level of voltage. When voltage is reversed, the IC chip regulates reverse current to flow through the IC chip and regulates reverse current not to flow through the LED.

### FIELD OF THE INVENTION

The present invention relates to a light emitting apparatus, and especially to a light emitting apparatus with current regulation function.

### BACKGROUND OF THE INVENTION

A light emitting diode (LED) is well known due to small size, power saving and longer lifetime. The LED usually radiates at least 100,000 hours or 10 years. As the luminance efficiency of the LED increases, it becomes a light source of next generation. However, the high cost limits the LED to be a major light source. Therefore, a lifetime guarantee becomes a key point to attract consumers.

When the LED serves as a light source, a power source is coupled to the LED for applying a voltage. The power source may be unstable and the voltage or a current through the LED varies. In this situation, the over voltage or the over current damages the LED. In U.S. Pat. No. 5,914,501, entitled “Light Emitting Diode Assembly Having Integrated Electrostatic Discharge Protection”, a method for protecting a LED from over-stress is disclosed. The LED is connected in parallel to a power shunting element. When a threshold voltage across the LED is exceeded, the power shunting element diverts electrical current from the LED and limiting the voltage across the LED to a clamp voltage.

However, the LED is a current-sensitive device. One major cause of the LED damaging and lifetime shortening is over current. Different kinds of the LED have different electric properties. Thus, under the same input voltage, currents through different kinds of the LED are in different levels. When room temperature varies, the current through the LED also varies as the same input voltage. In the situations aforesaid, voltage controlled can not provide sufficient protection to the LED from damaging by over currents. Sometimes the voltage is reversed because of careless assembling process, and the LED is destroyed by the reversed current.

Furthermore, for providing sufficient brightness or meeting with other applications, a light emitting device have to employ several LEDs (Light Emitting Diodes). These LEDs are connected in a parallel or a series configuration or both of them in the light emitting device. Ideally, each of LEDs in the light emitting device is operated under a correct bias and has an appropriate current through it. Nevertheless, it is not likely to ensure that each LED used in the light device is the same and is operated ideally.

In practice, each LEDs in a parallel configuration may require different biases. Consequently, some LEDs in the configuration may be destroyed by over current and some other LEDs may have inappropriate currents through them. One solution is a bin sorting method, but the accuracy of the method is limited. The problem still remains when the light emitting devices adopts different kinds of LEDs in its configuration.

### SUMMARY OF THE INVENTION

One aspect of the invention is to provide a light emitting apparatus with current regulated function. Thus, a current flows through the LED at a substantial constant as voltage varies.

Another aspect of the invention is to provide a light emitting apparatus with a LED therein. A reverse current does not flow through the LED when a voltage is reversed.

A light emitting apparatus includes a LED and an integrated circuit chip (IC chip). The IC chip is coupled to the LED by a flip-chip technology. The IC chip controls a current through the LED at a substantial constant value as the voltage varies. The IC chip makes the reverse current to flow through the IC chip and not to flow through the LED when the voltage is reversed.

A light emitting apparatus includes M light emitting units connected to each other. In each of the M light emitting units, a LED is coupled to an IC chip by a flip-chip technology. In each of the M light emitting units, the IC chip controls a current flowing through the LED at a substantial constant value as the voltage varies. The IC chip makes the reverse current to flow through the IC chip and not to flow through the light emitting diode when the voltage is reversed.

### BRIEF DESCRIPTION OF THE DRAWINGS

FIG. 1 is a cross-sectional view of the light emitting apparatus in accordance with the first embodiment of the present invention.

FIG. 2 is a circuit diagram of the first embodiment of the present invention.

FIG. 3 is a cross-sectional view of the light emitting apparatus in accordance with the second embodiment of the present invention.

### DETAILED DESCRIPTION OF THE INVENTION

For ensuring lifetime of the LED, the present invention provides a light emitting apparatus including a LED and an IC chip. The IC chip, coupled to the LED, regulates a current flowing through the LED. Thus, the LED is protected from over current damage.

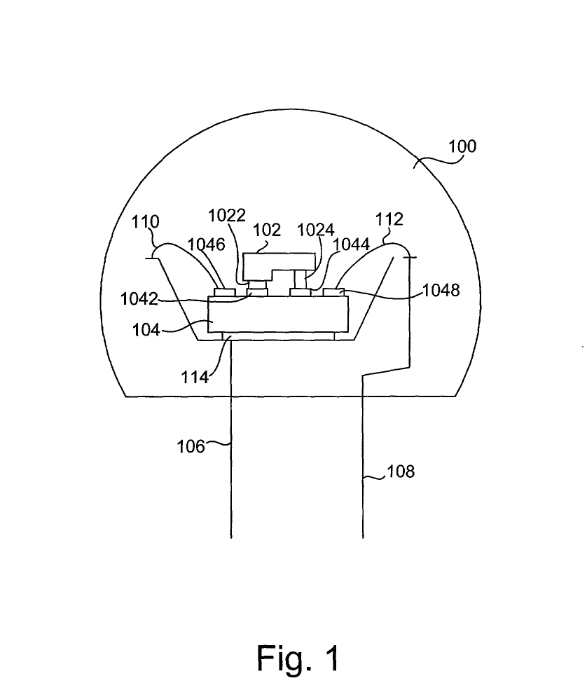

Please refer to FIG. 1. FIG. 1 is a cross-sectional view of the light emitting apparatus in accordance with the first embodiment. A LED 102 is coupled to an IC chip 104 by a flip-chip technology. The first and second electrical contacts 1022 and 1024 of the LED are on the same side of the LED 102. The IC chip 104 has the first pad 1042 and the second pad 1044. The first pad 1042 is electrically connected to the first contact 1022 and the second pad 1044 is electrically connected to the second electrical contact 1024. The LED is preferably a GaN based LED or an AlInGaP based LED. The description hereafter takes an through hole type LED as a preferred embodiment. It is appreciated by those skilled in the art that the present invention can apply to different kinds of LEDs.

The IC chip has the third pad 1046 and the forth pad 1048. A power source (not shown) is connected to the first electrode 106 and the second electrode 108. An isolating substrate 114 is formed on the first electrode 106 and the IC chip 104 is disposed on the isolating substrate 114. The first electrode 106 is wire bonding to the pad 1046 through the wire 110 and the second electrode 108 is wire bonding to the pad 1048 through the wire 112. Finally, these elements are molded in an epoxy resin or other transmissible material to from a package. Thus, a light emitting apparatus 100, such as a LED lamp, is provided.

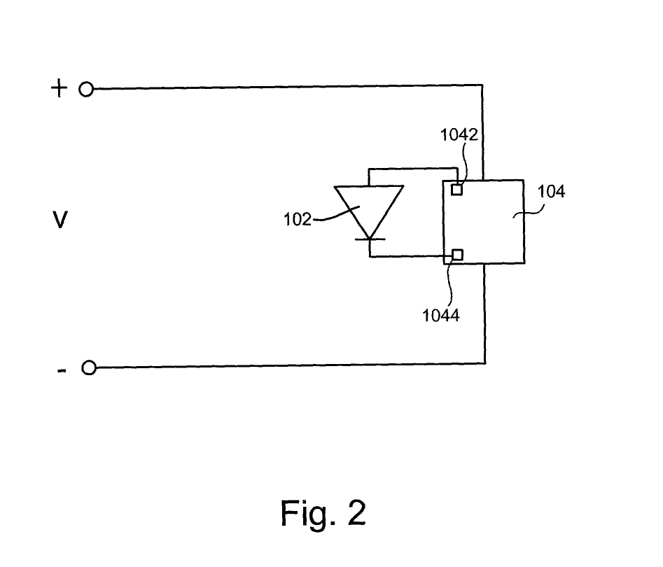

Please refer to FIG. 2. FIG. 2 is a circuit diagram of the LED apparatus as shown in FIG. 1. It is clear that the LED 102 is connected to the IC chip 104. Subsequently, the power source are electrically connected to the IC chip 104. In this configuration, the IC chip 104 regulates a current flowing through the LED 102. The power source applies a voltage to the light emitting apparatus 100 as shown in FIG. 1. However, the power source may be unstable and the voltage varies. In this situation, the IC chip 102 controls the current flowing through the LED at a substantial constant value. Thus the LED is protected from over current damage.

Moreover, the direction of the voltage may be reversed while assembling the power source and the light emitting apparatus. The IC chip 104 makes this reverse current to flow through the IC chip 104 and not to flow through the LED 102. Therefore, the LED 102 is not destroyed by reversed voltage.

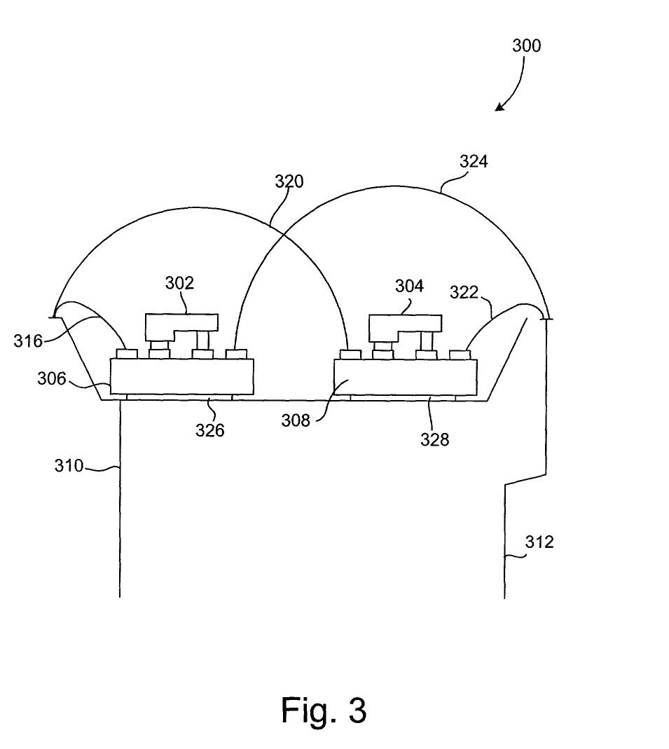

Furthermore, for providing sufficient brightness or meeting with other applications, a light emitting apparatus may have more than one LED. Please refer to FIG. 3. FIG. 3 is a cross-sectional view of the light emitting apparatus in accordance with the second embodiment and it shows two LEDs are assembled in one light emitting apparatus 300. A LED coupled to a IC chip forms a light emitting unit, such as the LED 302 coupled to the IC chip 306 and the LED 304 coupled to the IC chip 308. The connection between the LED and IC chip is the same as the aforesaid first embodiment and does not describe redundant.

All light emitting units are disposed on the first electrode 310 and the power source (not shown) is coupled to light emitting apparatus, as shown in FIG. 3. The isolating substrates 326 and 328 are formed on the first electrode 310 and the IC chips 306 and 308 are disposed on the isolating substrate 306 and 308, respectively. The pads of the IC chip 306 are electrically connected to the first electrode 310 and the second electrode 312 through the wire 316 and 324 respectively. The pads of the IC chip 308 are electrically connected to first electrode 310 and the second electrode 312 through the wire 320 and 322 respectively. Finally, these elements are molded in an epoxy resin or other transmissible material to from a package (not shown). Thus, a light emitting apparatus 300, such as a LED lamp, is provided.

The LED 302 and LED 304 may be different kind of the LEDs or may have different levels of currents while applying the same level of the voltage. In the present invention, each LED is coupled to a corresponding IC chip. The current through each LED, regulated by the corresponding IC chip, is in the same level and do not influence by different kinds of LEDs or voltage variation.

Moreover, the direction of the voltage may be reversed while assembling the power source and the light emitting apparatus 300. The IC chip makes this reverse current to flow through the IC chip itself and not to flow through the corresponding LED in each of the light emitting units. Therefore, the LED is not destroyed by reversed voltage.

The number of the light emitting units in a light emitting apparatus is not limited to 2. The number of the light emitting units in a light emitting apparatus can be as many as possible in accordance with applications and system limitations. The configuration of the light emitting unit can be in a parallel or series configuration or combination of them.

Although this invention has been described in its preferred form with certain degree of particularity, it is appreciated by those skilled in the art that present disclosure of the preferred form has been made only as an example and that numerous changes in the details of the construction, combination and arrangement of its parts may be resorted to without departing from the spirit and scope of the invention.

What is claimed is:

1. A light emitting apparatus comprising:
a light emitting diode; and
a current control component coupled to the light emitting diode;
wherein the current control component controls a current flowing through the light emitting diode at a substantial constant value as an input voltage varies.

2. The light emitting apparatus of claim 1, wherein the current control component is an integrated circuit chip.

3. The light emitting apparatus of claim 2, wherein a reverse current is produced when a direction of the input voltage is reversed, and the integrated circuit chip makes the reverse current to flow through the integrated circuit chip and not to flow through the light emitting diode.

4. The light emitting apparatus of claim 1, the light emitting diode is coupled to the current control component by a flip-chip technology.

5. A light emitting apparatus comprising:
M light emitting units connected to each other, each of the M light emitting units comprising a light emitting diode and a current control component, wherein the light emitting diode is coupled to the current control component;
wherein the current control component controls a current flowing through the light emitting diode at a substantial constant value as an input voltage varies.

6. The light emitting apparatus of claim 5, wherein the current control component is an integrated circuit chip.

7. The light emitting apparatus of claim 6, wherein a reverse current is produced when the direction of the input voltage is reversed, and the integrated circuit chip makes the reverse current to flow through the integrated circuit chip and r not to flow through the light emitting diode in each of the M light emitting units.

8. The light emitting apparatus of claim 5, the light emitting diode is coupled to the current control component by a flip-chip technology in each of the M light emitting units.

9. A light emitting apparatus comprising:
a light emitting diode; and
an integrated circuit chip coupled to the light emitting diode by a flip-chip technology;
wherein the integrated circuit chip controls a current flowing through the light emitting diode at a substantial constant value as an input voltage varies, and the integrated circuit chip makes the reverse current to flow through the integrated circuit chip and not to flow through the light emitting diode when the input voltage is reversed.

10. A light emitting apparatus comprising:
M light emitting units connected to each other, and each of the M light emitting units comprising a light emitting diode and an integrated circuit chip, wherein the light emitting diode is coupled to the integrated circuit chip by a flip-chip technology;
wherein, in each of the M light emitting units, the integrated circuit chip controls a current flowing through the light emitting diode at a substantial constant value as an input voltage varies, and the integrated circuit chip makes the reverse current to flow through the integrated circuit chip and not to flow through the light emitting diode when the input voltage is reversed.
